(19) United States
(12) Patent Application Publication
(10) Pub. No.: US 2002/0078412 A1
(43) Pub. Date: Jun. 20, 2002

(54) Built-in self test for a programmable logic device using linear feedback shift registers and hierarchical signature generation

(76) Inventors: Yongjiang Wang, Fremont, CA (US); Rafael C. Camarota, Sunnyvale, CA (US)

Correspondence Address: Donald R. Boys, P.O. Box 187, Aromas, CA, 95004, US

(21) Appl. No.: 09/738,055

(22) Filed: Dec. 14, 2000

(51) Int. Cl. H03K 19/177; H01L 25/00; G01R 31/28; G06F 7/02; H03M 13/00

(52) U.S. Cl. 714/732; 714/819

(57) ABSTRACT

A method for testing a programmable logic device having defined programmable function blocks with programmable interconnects follows steps of (a) configuring, by programming, two or more similar groups of the function blocks and interconnects into identical state machines; (b) operating the programmed state machines by clock and reset signals to generate individual original signatures on global interconnect lines; and (c) comparing the original signatures of the two or more state machines for fault detection. Original signatures from different programmed groups of function blocks and interconnects at different dedicated test output blocks are compressed and passed to signature analysis circuitry where a final signature is analyzed as in indicator of faults. A microcontroller is taught for configuring and performing tests.

### FIELD OF THE INVENTION

The present invention is in the field of integrated circuits (ICs) and pertains in particular to self testing for programmable logic.

### BACKGROUND OF THE INVENTION

The present invention is in the technical area of testing for integrated circuits (ICs). As is very well-known in the art, with the ascendancy of computers and computer devices in the last few decades, many millions of integrated circuits are regularly manufactured for the many more millions of computerized devices built and sold every year. It is also well-known that the manufacturing process for integrated circuits of all types is a very complicated and highly technical process that takes place necessarily in very expensive clean rooms. Moreover, ICs are typically implemented on silicon wafers, and each wafer typically yields a number of ICs.

It is very well-known in the art that testing is critically important in the manufacturing of ICs. Usually ICs are tested one-hundred percent, because each IC is typically relatively expensive, and because the function of the boards and devices into which ICs are assembled depends wholly on the ICs, and proper function and reliability is mandatory.

There are many different types of ICs in the art. Some are general in nature, such as microprocessors and other CPUs that operate by executing stored software code. Others are very specialized devices. Some are devices devoted to performing logic operations. The present patent application has particular application to ICs known as Programmable Logic Devices, which perform logic operations, and can be programmed to change the nature and sequence of the operation they perform.

For a variety of reasons ICs are tested to some level at a number of stages in manufacture, and at some point it is always necessary to test every part 100 percent for all of the functions the IC is designed to perform. This is true for programmable logic devices just as it is or other kinds of ICs, and programmable logic devices (PLDs) have a relatively broad range of functionality compared to other kinds of circuits.

The conventional testing method for a programmable logic device has three main components. The first of these is configuration data, which specifies the logic functions programmed into the PLD during tests. This is necessary for complete test so that all of the possible functions of a PLD may be tested. The second component necessary is a set of input vectors, which provide stimuli to configured PLD circuits during test. The third necessary component is the set of expected output vectors. The output vectors are compared against the actual outputs of the PLDs during test. If the actual output is different from the expected output, then the component, of course, fails the test.

Because of the considerable complexity of PLDs, the three components required for testing, as briefly described above, usually comprise a relatively large amount of data. This is not an insurmountable problem for offline testers, because computerized apparatus can be dedicated to the testing process, including large data repositories. If, however, one wishes to test PLDs that are embedded in larger chips and devices, which is an important object of the present patent application, then use of offline testers is generally not practical.

What is clearly needed is a new process, including apparatus and methods, for testing PLD structures without requiring storage of large amounts of configuration data, test vectors, and expected output vectors.

### SUMMARY OF THE INVENTION

In a preferred embodiment of the invention a method for testing a programmable logic device having defined programmable function blocks with programmable interconnects is provided, comprising the steps of (a) configuring, by programming, two or more similar groups of the function blocks and interconnects into identical state machines; (b) operating the programmed state machines by clock and reset signals to generate individual original signatures on global interconnect lines; and (c) comparing the original signatures of the two or more state machines for fault detection.

In some embodiments the method further comprises a step for receiving original signatures from different programmed groups of function blocks and interconnects at different dedicated test output blocks, comparing the signatures at the test output blocks, and passing the results of compare to further serially-connected test output blocks connected to further programmed function blocks and interconnects for further comparison. In some of these embodiments tests are conducted sequentially, from a first test output block to a final test output block, with the final result indicating the presence or absence of a fault anywhere on the programmable logic device.

In some embodiments there is a further step for receiving sequential data at a signature analyzer, reducing the data received to a single word by means of a linear feedback shift register circuit, and comparing the final word with a stored expected word to indicate pass or fail for the tested circuit.

In another aspect of the invention a test system for testing a programmable logic device having two or more groups of identical programmable function blocks and interconnects is provided, comprising configuration programming for configuring the function blocks and interconnects into identical state machines, clock and reset signals for operating the two or more state machines to generate individual original signatures, and comparison circuitry for receiving and comparing the original signatures as an indication of faults in the programmable logic device.

In some embodiments of the test system the programmable logic device is a Cartesian matrix of programmable cells interconnected by global lines, and the system may have test output circuits connected to global lines at the ends of rows and columns of the matrix, with the test output circuits connected serially by a test bus ending at an output port, characterized in that individual ones of the test output circuits are selectable, and when not selected pass a word received on the test bus on to the next test output circuit on the bus, and when selected compare the word received on the global lines with the word received on the test output bus, passing along the word received on the global lines to the test output bus, and if the words are different, setting a fault indicator than the word received on the test bus.

In some embodiments there is a signature analyzer circuit connected at the output port, wherein the signature analyzer circuit reduces sequential data received on the test bus to a single word, and compares the reduced word to a stored, expected word, a match indicating a tested programmable logic device without faults, and a mismatch indicating a programmable logic device with one or more faults.

In some embodiments the test system is implemented with a microcontroller, with the configuration data stored in a memory of the microcontroller, and the microcontroller enabled to configure the function blocks and interconnects into identical state machines, and to provide clock, reset, and select signals necessary to generate the original signatures and to compare the original signatures as fault indicators. In some cases a signature analyzer reduces test data to a single final word, and the microcontroller compares the final word to a stored word as an indication of pass or fail for the overall device.

In yet another aspect of the invention a programmable logic device (PLD) with built-in self-test (BIST) is provided, comprising a matrix of programmable function cells interconnected by programmable interconnects, an interface for accepting configuration data for configuring two or more function cells of the PLD into identical state machines, and an initiation mechanism for triggering the configured state machines each to index through their possible states, each outputting an original signature on the global lines, and circuitry for comparing the original signatures as an indication of possible faults in the PLD circuitry. In some embodiments the matrix is a Cartesian matrix interconnected by global lines.

In some embodiments the PLD further comprises test output circuits connected by the global lines at the ends of rows and columns of the Cartesian matrix, with the test output circuits connected serially by a test bus ending at an output port, characterized in that individual ones of the test output circuits are selectable in order, and upon selection compare a data word received on the test bus to a data word received on global lines from a programmed and initiated state machine, and pass the global line word on to the next serially-connected test output circuit along with an indication of the compare, and not selected do not compare, but pass a received data word on the test bus on to the next test output circuit.

In still other embodiments the PLD further comprises a signature analyzer circuit connected at the output port, wherein the signature analyzer circuit reduces data received on the test bus to a single word, and compares the reduced word to a stored, expected word, a match indicating a tested programmable logic device without faults, and a mismatch indicating a programmable logic device with one or more faults. The PLD may be an embedded device in a larger circuit.

In some embodiments the PLD comprises a microcontroller coupled to the interface for accepting configuration data, the microcontroller having a memory storing the configuration data, characterized in that the microcontroller programs the programmable function cells and interconnects into the identical state machines, controls the state machines to generate original signatures, and compares the signatures as an indication of faults. The PLD may further comprise test output circuits sequentially connected by a test bus to a signature analyzer, and the microcontroller further controls the test output circuits and test bus to compress data to the signature analyzer as a single word, comparing the single word to a stored test word as an indication of faults.

In yet another aspect a microcontroller is provided, comprising a memory, an interface to a programmable logic device (PLD), and a sequential program. In this microcontroller the memory stores configuration data, and in executing the sequential program configures groups of programmable function cells and interconnects of a connected PLD into identical state machines, initiates the configured state machines to generate original signatures, and compares the generated signatures to indicate faults in the PLD.

In some embodiments the microcontroller, in executing the sequential program, manages test output circuits coupled to programmed state machines, the test output circuits sequentially connected by a test bus to a signature analyzer, to compress data to the signature analyzer as a single word, and compares the single resulting test word to a word stored in the microcontroller memory as an indication of faults.

In various embodiments of the present invention taught in enabling detail below, for the first time a system and method is provided wherein programmable IC devices may be tested thoroughly in a way that minimizes time and effort, and also minimizes storage and manipulation of configuration data and test sequence data.

### BRIEF DESCRIPTION OF THE DRAWING FIGURES

FIG. 1 is a generalized diagram of a programmable logic device (PLD) with a structure and added elements according to an embodiment of the present invention.

FIG. 2 is a diagram of an original signal generator formed of a group of logic and interconnection circuits of the PLD of FIG. 1 in an embodiment of the present invention.

FIG. 3 is a diagram of a test output Block according to a preferred embodiment of the present invention.

FIG. 4 is a diagram of a signature analyzer according to an embodiment of the present invention.

FIG. 5 is a diagram showing a microprocessor used in an embodiment of the invention.

### DESCRIPTION OF THE PREFERRED EMBODIMENTS

As is well-known in the art, a Programmable Logic Device (PLD) is an integrated circuit having a matrix of interconnected programmable cells. The cells may be of several different types, but each cell typically includes both programmable logic elements and programmable interconnect elements, such that a variety of functions may be programmed. The advantage of such devices is that one standard PLD may be used in a wide variety of different ways. Without the advantage of PLDs every function would require a dedicated circuit design and development.

It is further well known in the art that there are a wide variety of PLD devices available in the art from a variety of different manufacturers. An object of the present invention is to enhance PLD structures, by implementing on-chip built-in self-test (BIST), so they may be thoroughly tested without the use of conventional external testers. The invention is implemented in preferred embodiments by organizing elements of a target PLD into specialized arrangements, which requires that certain generic elements, such as register, programmable interconnect, and logic elements be present. These elements are typically present in the vast majority of PLDs, and necessarily so, and therefore the inventors believe the structure and methods of the present invention in its various embodiments will be applicable for BIST of most existing and future PLD types and structures.

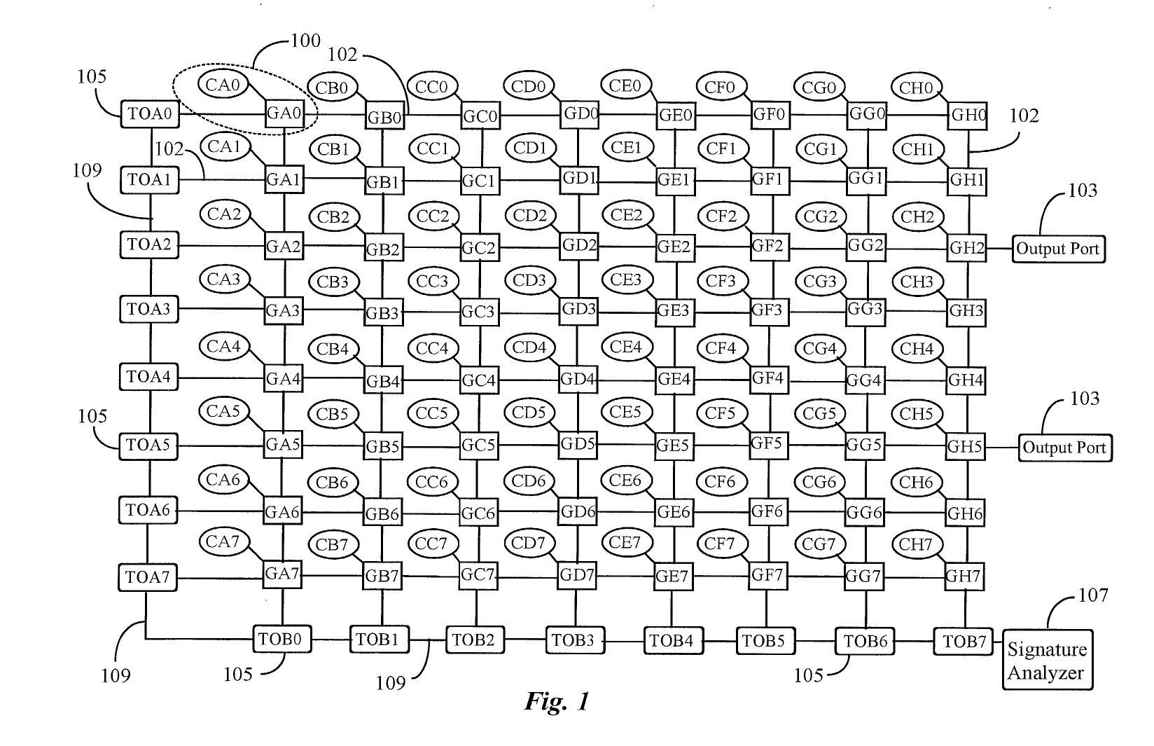

FIG. 1 is a generalized diagram of a programmable logic device (PLD) with architectural structure and added elements according to an embodiment of the present invention. As described briefly above, a PLD is typically a matrix of cells, each cell of which contains logic elements, programmable interconnect elements allowing the logic elements to be interconnected in a variety of ways, and global interconnect lines interconnecting the matrix of cells. There may be several different sorts of cells, but there are usually many repetitions of cells as well. The present inventors have discovered that PLDs can be divided into groups of cells which can each be configured (by programming) into similar groups of elements that can be operated as identical state machines.

FIG. 1 illustrates a PLD with the cells of the PLD organized into a matrix of groups of cells each of which provides a state machine as an original signature generator, as will become more clear in further disclosure below. Each group of cells is shown divided into two separate groups, one of programmable logic elements, and the other of programmable interconnect elements. For example, one grouping 100 in FIG. 1 is illustrated as comprising a grouping CA0 of programmable function blocks, and a grouping GA0 of programmable interconnect elements. The matrix nature of the array is illustrated by columns A through H and rows 0 through 7, in this example. CA0 therefore represents the logic elements of the first column (A) and the first, or topmost, row (0). Similarly GA0 represent the programmable interconnect elements of the same cell block. In like manner every block is thus identified in FIG. 1 by the nature of the programmable elements and the row and column position in the array.

As briefly indicated above all of the cells or blocks of the array are interconnected by global interconnect lines, of which several, but not all, are indicated herein by the element number 102. Not all are so indicated, in order to avoid confusion, but it will be apparent to the skilled artisan that the global lines are all of the lines shown interconnecting the function cells into a Cartesian array, and also connecting each row and column of function cells to an added test output structure (to be described in further detail below).

It will further be apparent to the skilled artisan that the architecture shown, as it pertains to existing and conventional PLDs, is representative and exemplary, rather than detailed and specific. There may be many more than the cells shown, and the number of columns and arrays may vary widely as well.

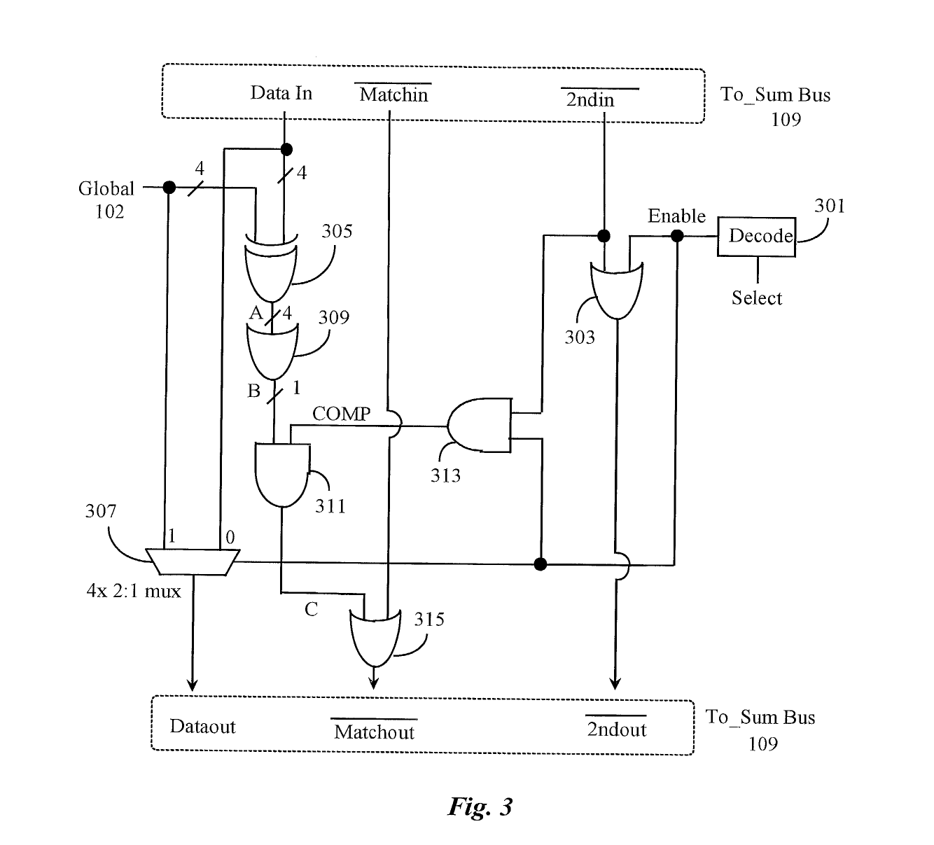

In the example of FIG. 1 there are two output ports 103 illustrated, and these are a generic component of literally all PLDs, as every PLD must have an ability to provide outputs according to generated inputs, as this is the function of a PLD. In addition, there is, for each row and column, a test output compressor block 105. The test output compressors for rows are labeled with A and sequentially from 0 to 7. The test output compressors for columns are labeled with B and also sequentially from 0 to 7. The position of each test output block, however, makes it quite clear which row and column is served. The function of the test Output blocks is discussed in additional detail below, with reference to FIG. 3. The test output blocks are connected one to another serially by a TO_Sum bus 109 from block TOA0 sequentially to block TOB7. Test signatures from especially configured function cell groups are passed to the test output blocks on the Global lines, and comparisons are made as tests proceed, as will be apparent from following description, indicating whether or not a fault is detected. There is also a select bus with a connection to each test output block, although this bus is not shown to avoid confusion.

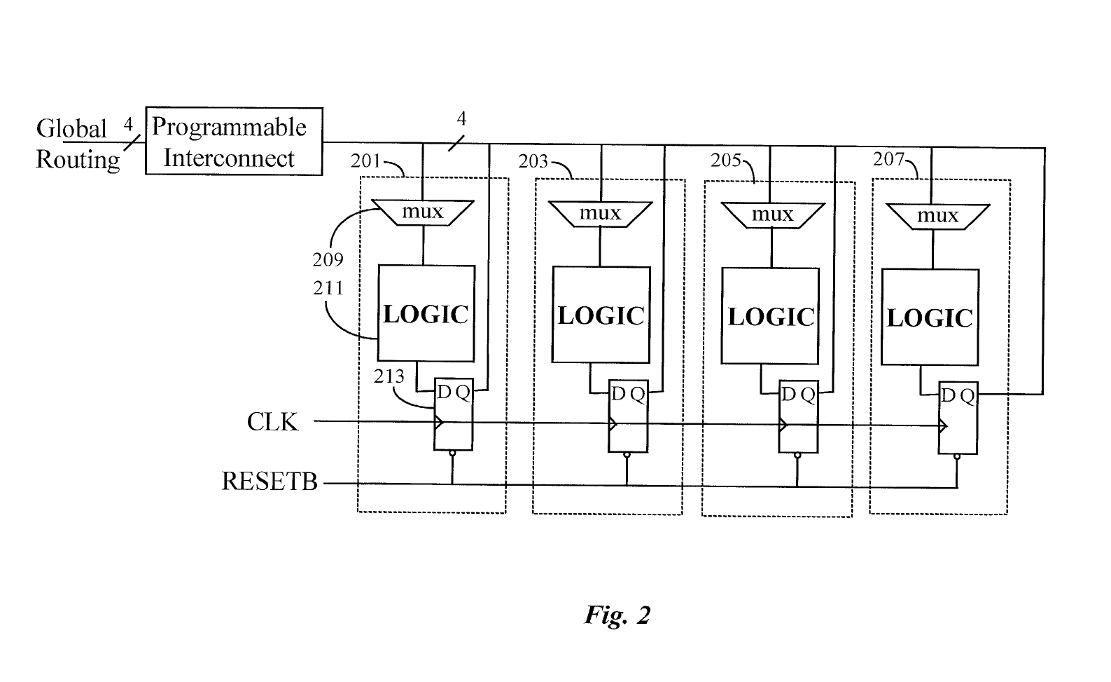

FIG. 2 illustrates how groupings 100 of FIG. 1 are configured to provide original signature generators, and to perform novel testing according to certain embodiments of the present invention. In a preferred embodiment each grouping 100 is configured as a finite state machine circuit. Referring now to FIG. 2, there are shown in this embodiment four macros 201, 203, 205 and 207, which are essentially identical in architecture, each having a multiplexer (mux) 209, a logic block 211 which includes a register, and a flip-flop circuit 213. The equivalent elements for macros 203, 205 and 207 are not numbered.

In addition to configuring the logic portions (CA, CB, CC and so on) for each grouping of cells into, in this case a four element state machine, the programmable interconnect elements (GA, GB, GC and so on) are configured to connect the logic elements as shown. It is known in the art that each cell has clock and reset signals, which in this example are configured to be connected to the flip-flop circuits as shown.

In a preferred embodiment tests are done selectively for circuitry regions on a candidate IC. For example, for some ICs the logic and interconnect elements may be consistent row by row and column by column, and for some ICs the elements may be less consistent, such that portions of rows and columns may have to be configured differently to make state machines that will test all of the logic and interconnect functionality. The structure of a candidate PLD will determine the configuration and the order in which testing may be done. One may therefore configure and conduct a series of tests that will fully test a portion of the overall candidate device, and then configure and test another portion, until the entire device is thoroughly tested.

It is emphasized again that the four-macro state machine shown is a single example applicable to certain PLD designs, and that other architectures may require different configured designs for original signature generation than that shown in FIG. 2. In other cases the configuration is based on the amount of PLD resources required in the specific instances to create an original signature generator. It is believed by the inventors that essentially any PLD architecture can be evenly divided into identical regions of function cells and routing resources, capable of implementing an appropriate set of original signature generators.

In operation a reset signal resets a state machine to an original “home” state, and a clock signal initiates a signature sequence. When a signature sequence completes, it also terminates. The state machine shown can have a maximum of sixteen different states. Because PLD input muxes, local logic function and output connections are configurable, there has to be more than one configuration to test all possible functional logic combinations and programmable interconnect combinations. The criteria for the finite state machines is that all of the possible PLD logic and PLD internal nodes are checked at least once for stuck-at-1 and stuck-at-0 faults by accumulating the results of all different configurations. Each state machine only needs to generate enough different states, and to have those states stimulate enough PLD circuitry in it and around it to achieve coverage of nodes, paths, logic elements and their associated memory cells unique to the particular PLD system.

The finite state machine generates the sequences of data, which are called the original signature. The global routing conducts the signature generated to the boundary of the array. As each function block CA0+GA0, for example, is tested, sequential data (the original signature), is generated on the global lines, and is captured by the local test-output compressor, such as TOA0 in this example. The test output compressor structures TOA0 through TOA7 and TOB0 through TOB7 are added structures according to an embodiment of the present invention, not normally present in PLDs. In some cases, however, the test output structures may be configured from existing elements of a PLD.

FIG. 3 is a diagram illustrating detail in a preferred embodiment for test output blocks, such as TOA0. The test output blocks perform original signature comparison and a form of compression of values of the global routing output signals, which is then passed on the TO_Sum bus. A select input to a decode block 301 is used to determine, for different blocks, which blocks are to do a compare and which are to pass TO_Sum data through. Decode block 301 produces an enable “1” when the particular test output block is selected.

The TO_Sum bus which connects all of the test output blocks, has data lines, a match signal, and a 2nd signal, and each test output block has a datain and a dataout port, a Matchin and a Matchout port, and a 2ndin and a 2ndout port, as shown. 2ndin and Enable for each test output block go to an OR 303, which produces 2ndout. 2nd out will be “1” if either 2ndin is “1” or the current block is selected, therefore this signal lets all downstream test Output blocks know that at least one upstream block was previously selected.

The Datain bus is the same width as the global bus, and transfers the data from the last upstream test output block that was selected. The Datain lines go to a set of two input exclusive OR gates 305 and a set of muxes 307. The Global input bus to the test output block comes from the periphery of the PLD matrix (see FIG. 1). The width of the global bus is a function of the complexity of the particular Original Signature Generator. The width of the Global bus determines the width of the Datain, Dataout and A buses. The “A” bus proceeds from the set of two input exclusive OR gates 305. The global bus also goes to one input of the set of two input exclusive OR gates 305 and the set of muxes 307.

Dataout is the output of muxes 307, and drives the Datain for the next downstream test output block. Dataout is equal to the Global bus signal when the test output block is selected in every case but the case in which the test output block is the first upstream block. In that case, there is no compare, and the data word on the Global input is passed through to the next downstream test output block.

When not selected a test output block that is not the first block passes Datain through to Dataout. There is a mux 307 for each bit on the Global bus, and for each bit of the Datain or Dataout signal. Similarly there is a set of an exclusive OR gates 305, with one for each bit of the Global bus and each bit of the Datain signal. The output of the exclusive OR gates 305 is bus “A”, of the same width as the Global bus and the Datain and Dataout signals.

Bus “A” goes to one OR gate 309 which has a number of inputs equal to the number of bits in bus “A”, in this example, four. The single bit output of OR 309 is line “B”. The bit value on line “B” is 0 when the Datain and the Global signal are a match, as per the exclusive OR set 305. If any one or more bits of the Datain and the Global signal do not match, the output to bus “B” is 1.

The value on line “B” is one input to AND gate 311. The second input to AND gate 311 is called COMP, and is the output value of AND gate 313, whose inputs are ENABLE and 2ndin. When the particular test Output block is selected, Enable is 1, and if the particular block is not the first selected, 2ndin is also 1, which results in a COMP value of “1”. As described above, when Datain and Global are a match, line “B” is 0. When the Datain and the Global do not match, “B” is 1. Output “C” of AND gate 311 goes to OR gate 315, whose second input is Matchin from the TO_Sum bus from the next upstream test Output block, and whose output is Matchout to the TO_Sum bus to the next downstream test output block.

The summary result of the circuitry of the test output compressor blocks as described hereinabove is that each test output block may be selected in order from the first upstream to the last downstream block, as each original signature generator in the PLD array is sequentially operated, testing the underlying circuitry, and if Datain and Global continue to match, Matchin at the next block will always be 0. If, for any selected block, the Datain and the Global do not match, the Matchout signal will be 1, and the Matchin/Matchout will propagate 1 downstream to the end of the test output block chain, indicating a fault in the test somewhere upstream.

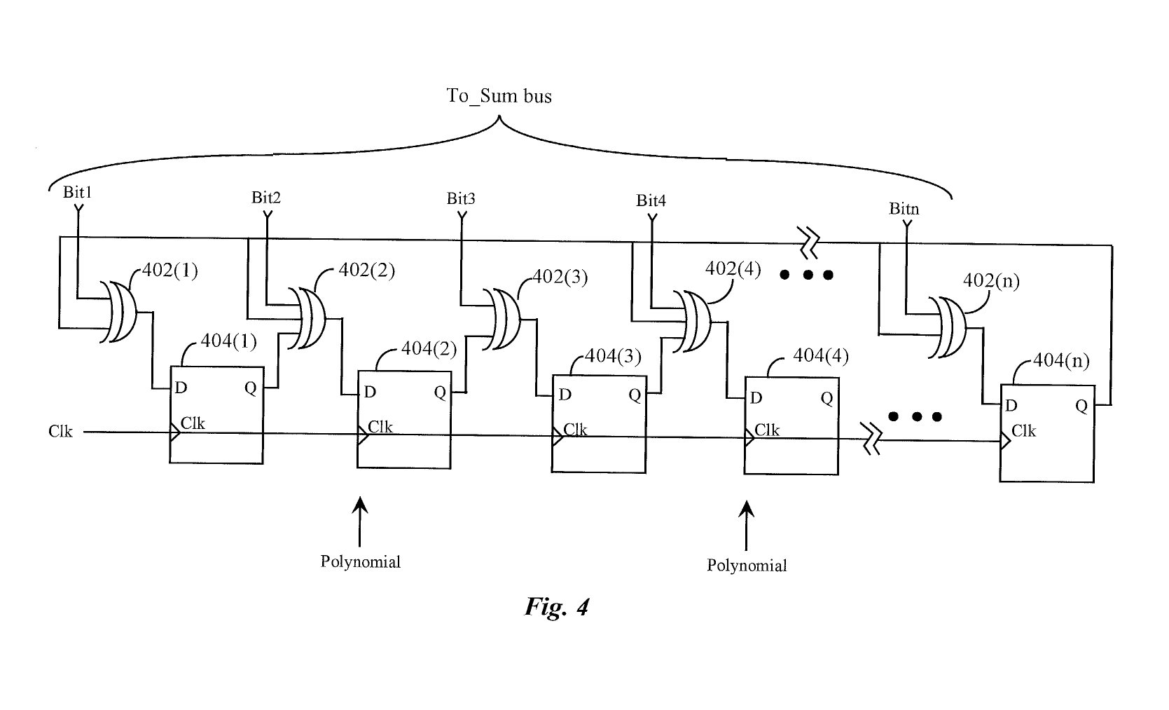

Referring again to FIG. 1, at the end of the TO_Sum bus chain, from TOB7, the TO_Sum bus goes to a signature analyzer block 107. FIG. 4 is a diagram of this signature analyzer 107. The final signature analyzer as shown in FIG. 4 is a Linear Feedback Shift Register (LFSR) implemented as a compaction mechanism for capturing the collection of original signatures and compacting them into a unique word.

Referring now to FIG. 4, the signature analyzer is implemented, as indicated above, as a LFSR. Each bit of the TO_Sum bus is one input to an exclusive OR. For example, Bit 1 of the Datain of the To-Sum bus is an input to XOR 402(1), Bit2 is an input to XOR 402(2), and so on to Bitn and XOR 402(n). In some cases there will be more bits in the LSFR than in the To_Sum bus, in which case unused bit in signals of the LSFR will be tied to 0. The output of each XOR is an input to a flip flop. For example, output of XOR 402(1) goes to the “D” input of flip-flop 404(1), and so on, as shown.

If the LFSR is initialized to a nonzero value, it can cycle through a number of states before returning to the initial state. If the n-bit LFSR has primitive characteristic polynomial, it will cycle through all 2ⁿ−1 possible nonzero states.

Since the original signature generation in this example generates 16 sequences of data, each underlying original signature generator block needs multiple configurations (M) to complete full coverage, each global routing block needs multiple configurations (N) to complete full coverage, and there are multiple columns (P) needed to complete a full chip test. Therefore, for a full chip test the total data into the signature analyzer will have 16*M*N*P sequences of data with width W. For this reason the signature analyzer is designed to have a maximum number of LSFR states greater than 16*M*N*P*W. The data can be direct from PLD test output ports, which will result in a wide input bus to the signature analyzer, or with the use of the compaction method provided herein, the data will be a compacted word.

For a circuit without faults, the final result will be a predetermined n-bit word. The expected n-bit word for a no-fault chip is stored on the chip, and if the compacted word matches the expected word, the circuit passes the test. If the final compacted word does not match the expected word the circuit fails.

It is, of course, necessary to program the PLD circuitry into the desired original signature generators for the test to be performed. For this purpose, for a stand-alone PLD, a test device is connected to the PLD inputs, and the needed BIST programming is provided, as well as the clock and reset sequences needed for the test to be performed, and the final flag is received indicating the positive or negative result. For embedded structures, such as PLDs implemented as a part of larger circuitry, such as a computer on a chip, for example, the BIST programming is stored on the larger chip with a mechanism for initiating and conducting the test, and indicating the test result.

In either case, the BIST system provided in embodiments of the present invention programs the PLD into special structures, which generate data to test themselves without external data input beyond the original configuration, except for reset and clock signals. The self-test configured structures are local structures, and do not have strong attachment to their geometric locations. The structures can be replaced in a very repetitive manner, which means that a very small amount of data for programming can be used repeatedly, saving otherwise needed storage space. With the help of the small additional circuitry of the signature analyzer described in one embodiment herein, the programmably configured original signature generators can send their sequences of data to the added test output blocks, which compress values from many parallel tests to one final word, which serves as a flag that the circuit passes or fails.

In a number of preferred embodiments of the present invention a microcontroller is provided and included, wherein the necessary data for configuring programmable function cells and interconnects into state machines is stored in a memory of a special microcontroller, and the microcontroller is enabled to couple to a target programmable IC device, allowing the microcontroller to execute a sequential program configuring the programmable device into state machines, which the microcontroller then operates to produce original signatures, and to manipulate the signatures too determine possible faults in the device.

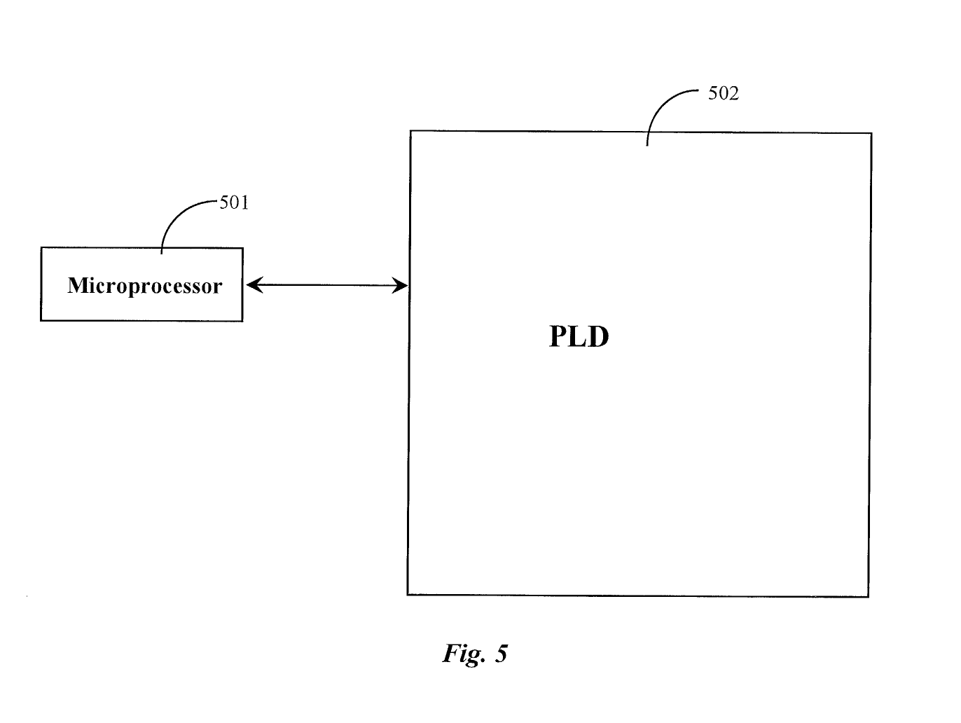

FIG. 5 illustrates a special microcontroller 501 according to the present invention coupled to a PLD 502. The PLD and microcontroller may be, in preferred embodiments, a part of a larger circuitry, such as a computer-on-a-chip.

In those cases wherein a target device may have or be configured to have test output circuits, a test bus, and a signature analyzer, the microcontroller may also, through program execution, manipulate the test structures and bus to provide a final single word to the signature analyzer, which is compared to a stored test word as an indication of pass of failure for the device under test.

It will be apparent to the skilled artisan that there are many variations that may be made to the specific embodiments of the present invention described above, without departing from the spirit and scope of the invention. There are a variety of ways, for example, that different PLDs may be configured into original signature generators. There are similarly a variety of ways that test outputs may be captured and analyzed. Further, the invention in alternative embodiments may be used for stand-alone and embedded PLDs, and for virtually any programmable logic devices or field-programmable gate array devices. The invention is to accorded the breadth of the claims that follow.

What is claimed is:

1. A method for testing programmable logic having defined programmable function blocks with programmable interconnects, comprising the steps of:
(a) configuring, by programming, two or more similar groups of the function blocks and interconnects into identical state machines;
(b) operating the programmed state machines by clock and reset signals to generate individual original signatures on global interconnect lines; and
(c) comparing the original signatures of the two or more state machines for fault detection.

2. The method of claim 1 further comprising a step for receiving original signatures from different programmed groups of function blocks and interconnects at different dedicated test output blocks, comparing the signatures at the test output blocks, and passing the results of compare to further serially-connected test output blocks connected to further programmed function blocks and interconnects for further comparison.

3. The method of claim 2 wherein tests are conducted sequentially, from a first test output block to a final test output block, with the final result indicating the presence or absence of a fault anywhere on the programmable logic device.

4. The method of claim 3 further comprising a step for receiving sequential data at a signature analyzer, reducing the data received to a single word by means of a linear feedback shift register circuit, and comparing the final word with a stored expected word to indicate pass or fail for the tested circuit.

5. A test system for testing a programmable logic device having two or more groups of identical programmable function blocks and interconnects, comprising:
configuration programming for configuring the function blocks and interconnects into identical state machines;
clock and reset signals for operating the two or more state machines to generate individual original signatures; and
comparison circuitry for receiving and comparing the original signatures as an indication of faults in the programmable logic device.

6. The test system of claim 5 wherein the programmable logic device is a Cartesian matrix of programmable cells interconnected by global lines.

7. The test system of claim 6 further comprising test output circuits connected to global lines at the ends of rows and columns of the matrix, with the test output circuits connected serially by a test bus ending at an output port, characterized in that individual ones of the test output circuits are selectable, and when not selected pass a word received on the test bus on to the next test output circuit on the test output bus, and when selected compare the word received on the global lines with the word received on the test output bus, passing along the word received on the global lines to the test output bus, and if the two words are different, a fault indicator is set on the test output bus.

8. The test system of claim 7 further comprising a signature analyzer circuit connected at the output port, wherein the signature analyzer circuit reduces sequential data received on the test bus to a single word, and compares the reduced word to a stored, expected word, a match indicating a tested programmable logic device without faults, and a mismatch indicating a programmable logic device with one or more faults.

9. The system of claim 5 implemented with a microcontroller, with the configuration data stored in a memory of the microcontroller, and the microcontroller enabled to configure the function blocks and interconnects into identical state machines, and to provide clock, reset, and select signals necessary to generate the original signatures and to compare the original signatures as fault indicators.

10. The system of claim 9 wherein a signature analyzer reduces test data to a single final word, and the microcontroller compares the final word to a stored word as an indication of pass or fail for the overall device.

11. A programmable logic device (PLD) with built-in self-test (BIST), comprising:
a matrix of programmable function cells interconnected by programmable interconnects,
an interface for accepting configuration data for configuring two or more function cells of the PLD into identical state machines, and an initiation mechanism for triggering the configured state machines each to index through their possible states, each outputting an original signature on the global lines; and
circuitry for comparing the original signatures as an indication of possible faults in the PLD circuitry.

12. The PLD of claim 11 wherein the matrix is a Cartesian matrix interconnected by global lines.

13. The PLD of claim 12 further comprising test output circuits connected by the global lines at the ends of rows and columns of the Cartesian matrix, with the test output circuits connected serially by a test bus ending at an output port, characterized in that individual ones of the test output circuits are selectable in order, and upon selection compare a data word received on the test bus to a data word received on global lines from a programmed and initiated state machine, and pass the global line word on to the next serially-connected test output circuit along with an indication of the compare, and not selected do not compare, but pass a received data word on the test bus on to the next test output circuit.

14. The PLD of claim 13 further comprising a signature analyzer circuit connected at the output port, wherein the signature analyzer circuit reduces data received on the test bus to a single word, and compares the reduced word to a stored, expected word, a match indicating a tested programmable logic device without faults, and a mismatch indicating a programmable logic device with one or more faults.

15. The PLD of claim 14 wherein the PLD is an embedded device in a larger circuit.

16. The PLD of claim 11 further comprising a microcontroller coupled to the interface for accepting configuration data, the microcontroller having a memory storing the configuration data;
characterized in that the microcontroller programs the programmable function cells and interconnects into the identical state machines, controls the state machines to generate original signatures, and compares the signatures as an indication of faults.

17. The PLD of claim 16 wherein the PLD further comprises test output circuits coupled to programmed state machines, the test output circuits sequentially connected by a test bus to a signature analyzer, and the microcontroller further controls the test output circuits and test bus to compress data to the signature analyzer as a single word, comparing the single word to a stored test word as an indication of faults.

18. A microcontroller comprising:
a memory;
an interface to a programmable logic device (PLD); and
a sequential program;
characterized in that the memory stores configuration data, and in executing the sequential program configures groups of programmable function cells and interconnects of a connected PLD into identical state machines, initiates the configured state machines to generate original signatures, and compares the generated signatures to indicate faults in the PLD.

19. The microcontroller of claim 18 wherein, in executing the sequential program the microcontroller manages test output circuits coupled to programmed state machines, the test output circuits sequentially connected by a test bus to a signature analyzer, to compress data to the signature analyzer as a single word, and compares the single resulting test word to a word stored in the microcontroller memory as an indication of faults.
